(19) United States
(12) Patent Application Publication
(10) Pub. No.: US 2025/0259947 A1
(43) Pub. Date: Aug. 14, 2025

(54) Semiconductor Device and Method of Forming AIP Package Structure from Separate Assemblies with Bonding Material

(71) Applicant: STATS ChipPAC Pte. Ltd., Singapore (SG)

(72) Inventors: Danfeng Yang, Jiangyin (CN); ShaSha Zhou, Jiangyin (CN); Linda Pei Ee Chua, Singapore (SG); Yaojian Lin, Jiangyin (CN); Hin Hwa Goh, Singapore (SG)

(73) Assignee: STATS ChipPAC Pte. Ltd., Singapore (SG)

(21) Appl. No.: 18/437,000

(22) Filed: Feb. 8, 2024

(51) Int. Cl. H01L 23/66; H01L 21/56; H01L 23/00

(52) U.S. Cl. CPC H01L 23/66; H01L 21/565; H01L 24/27; H01L 24/29; H01L 24/32; H01L 24/83; H01L 24/97; H01L 2223/6677; H01L 2224/27318; H01L 2224/2919; H01L 2224/32265; H01L 2224/83201; H01L 2224/97; H01L 2924/1815; H01L 2924/182; H01L 2924/19104

(57) ABSTRACT

A semiconductor device has a semiconductor assembly and an antenna substrate formed separate from the semiconductor assembly and mounted to the semiconductor assembly. A bonding material is disposed between the antenna substrate and semiconductor assembly. An encapsulant is deposited over the antenna substate. The encapsulant may be planar or have encapsulant bumps. The bonding material extends over a side surface of the antenna substrate. The antenna substrate has a first antenna substrate and a second antenna substrate disposed over the semiconductor assembly. The first antenna substrate is offset with respect to the second antenna substrate in the horizontal and/or vertical directions. The antenna substrate can fan out from the semiconductor assembly. The semiconductor assembly can have multiple layers of core material with different coefficient of thermal expansions. A heat sink or shielding layer can be formed over the antenna substrate and semiconductor assembly.

### FIELD OF THE INVENTION

The present invention relates in general to semiconductor devices and, more particularly, to a semiconductor device and method of forming an antenna-in-package (AiP) package structure from separate assemblies with bonding material.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system-in-package (SiP) module for higher density in a small space and extended electrical functionality. Within the SiP module, semiconductor die and IPDs are disposed on a first surface of a substrate for structural support and electrical interconnect. An encapsulant is deposited over the semiconductor die, IPDs, and substrate.

An antenna can be disposed on a second surface of the substrate to provide wireless communication for the SiP module. With the addition of the antenna, the SiP constitutes an AiP. In many cases, there is a long cycle time with each sequential wafer level AiP process. The antenna and fan-out package are typically made the same size in the same sequential wafer level AiP process. The known good antenna or known good package are difficult to match leading to excessive losses and low manufacturing yield.

### BRIEF DESCRIPTION OF THE DRAWINGS

FIGS. 1a-1d illustrate a semiconductor wafer with a plurality of semiconductor die separated by a saw street;

FIGS. 2a-2j illustrate a process of forming a semiconductor assembly;

FIGS. 3a-3f illustrate a process of forming an antenna substrate;

FIGS. 4a-4b illustrate disposing bonding material over the semiconductor assembly;

FIGS. 5a-5c illustrate mounting the antenna substrate to the semiconductor assembly;

FIGS. 6a-6b illustrate the antenna substrate mounted to the semiconductor assembly with encapsulant bumps;

FIGS. 7a-7b illustrate another embodiment of the antenna substrate mounted to the semiconductor assembly without encapsulant bumps;

FIG. 8 illustrates another embodiment with separate antenna substrates mounted to the semiconductor assembly;

FIGS. 9a-9b illustrate another embodiment with separate and offset antenna substrates mounted to the semiconductor assembly with and without encapsulant bumps;

FIG. 10 illustrates another embodiment with a fan-out antenna substrate mounted to the semiconductor assembly;

FIG. 11 illustrates the antenna substrate mounted to the semiconductor assembly with multiple layers of core material of different CTE;

FIGS. 12a-12b illustrate another embodiment with separate and offset antenna substrates mounted to the semiconductor assembly;

FIGS. 13a-13d illustrate another embodiment with a heat sink and/or shielding material formed over the antenna substrates and semiconductor assembly; and

FIG. 14 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

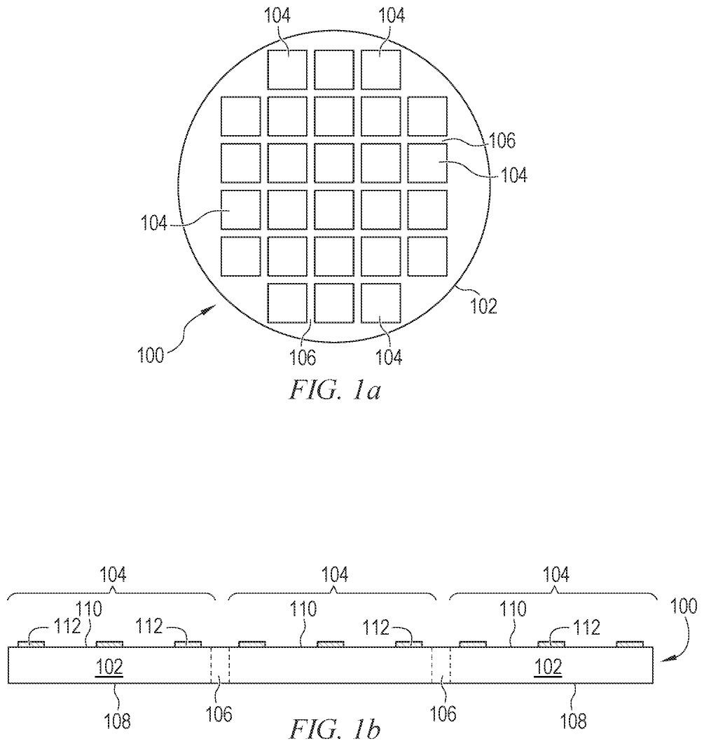

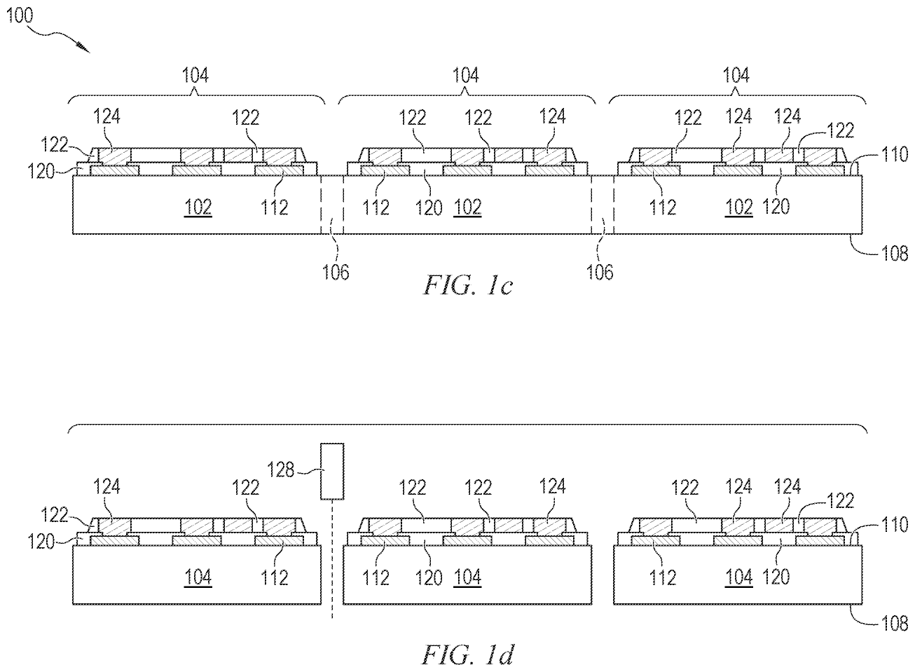

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Semiconductor die 104 can process RF signals transmitted and received through an antenna.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing. In one embodiment, semiconductor die 104 is a monolithic microwave integrated circuit (MMIC) or system-on-chip (SoC) type die.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, insulating layer 120 is formed over surface 110 and conductive layer 112. Insulating layer 120 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layer 120 can be formed using PVD, CVD, printing, lamination, spin coating, spray coating, sintering or thermal oxidation. A portion of insulating layer 120 is removed by etching or laser direct ablation (LDA) to expose conductive layer 112.

An electrically conductive layer 124 is formed over insulating layer 120 and conductive layer 112 using PVD, CVD, electrolytic plating, electroless plating process, or other suitable metal deposition process. Conductive layer 124 can be one or more layers of Al, Cu, Sn, Ni, Au, Ag, or other suitable electrically conductive material. Portions of conductive layer 124 can be electrically common or electrically isolated depending on the design and function of electrical components attached thereto. In one embodiment, conductive layer 124 operates as contact pads electrically connected to the circuits on active surface 110. In another embodiment, conductive layer 124 is a redistribution layer (RDL) as it redistributes the electrical signals over and across semiconductor die 104.

An insulating layer 122 is formed over insulating layer 120 and conductive layer 124. Insulating layer 122 contains one or more layers of SiO2, Si3N4, SiON, Ta2O5, Al2O3, solder resist, polyimide, BCB, PBO, and other material having similar insulating and structural properties. Insulating layer 122 can be formed using PVD, CVD, printing, lamination, spin coating, spray coating, sintering or thermal oxidation. Insulating layer 122 can be formed prior to conductive layer 124.

In FIG. 1d, semiconductor wafer 100 is singulated through saw street 106 using a saw blade or laser cutting tool 128 into individual semiconductor die 104. The individual semiconductor die 104 can be inspected and electrically tested for identification of known good die or unit (KGD/KGU) post singulation.

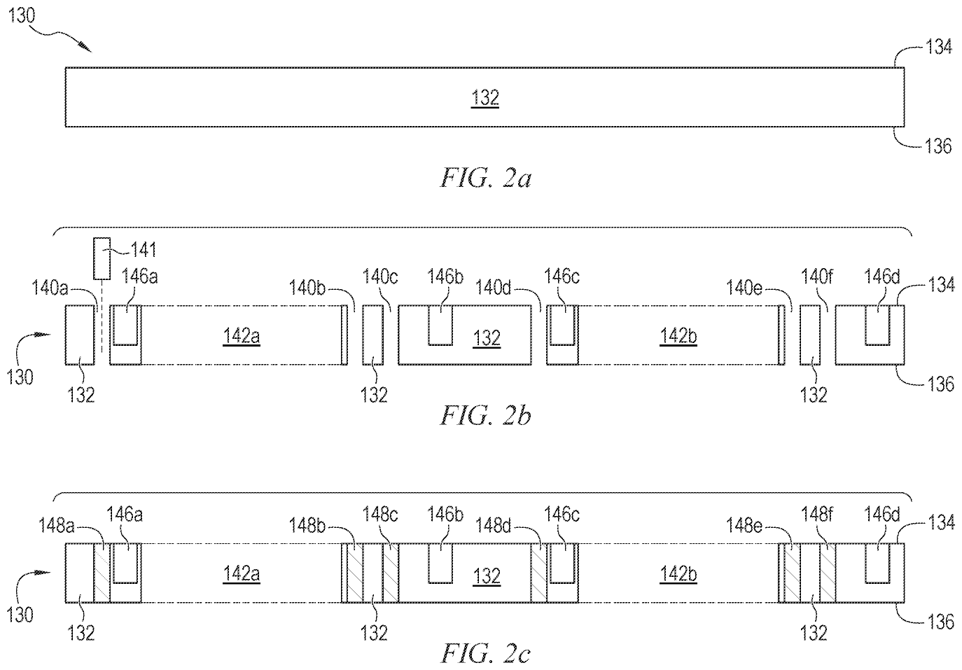

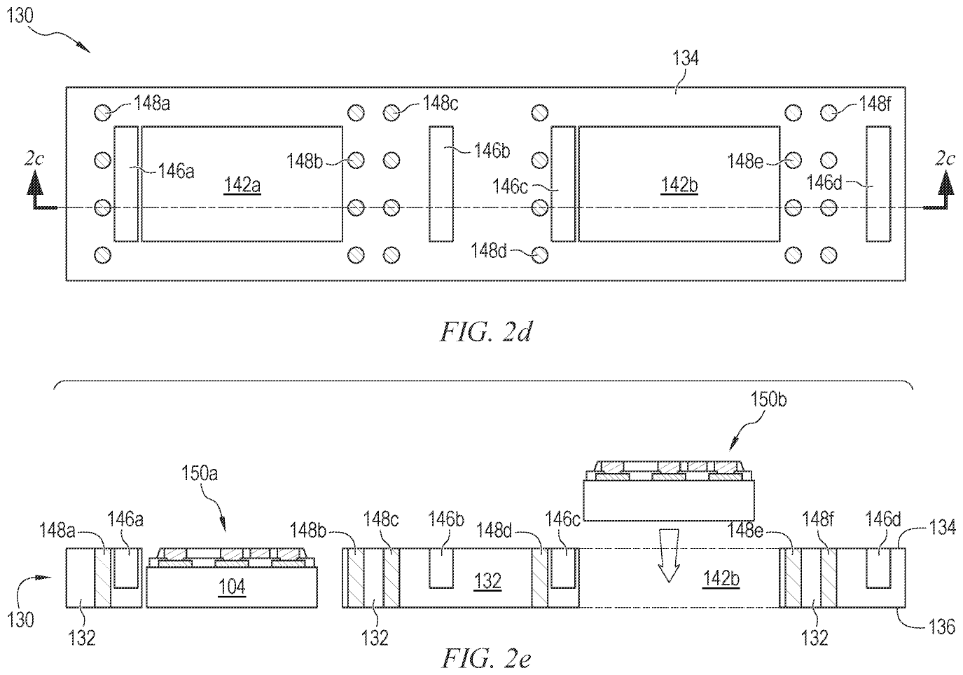

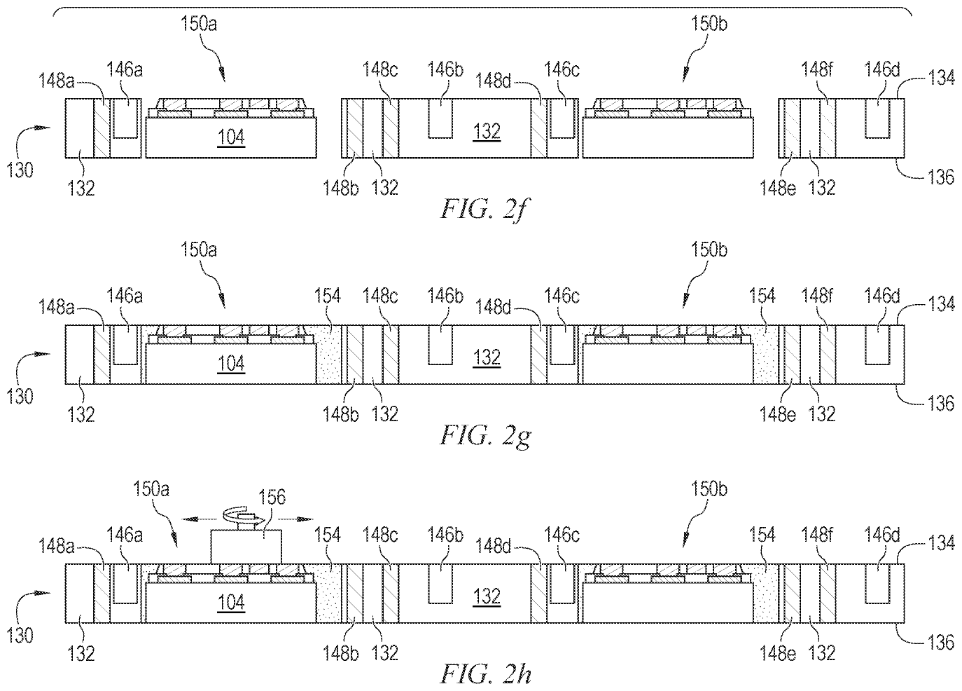

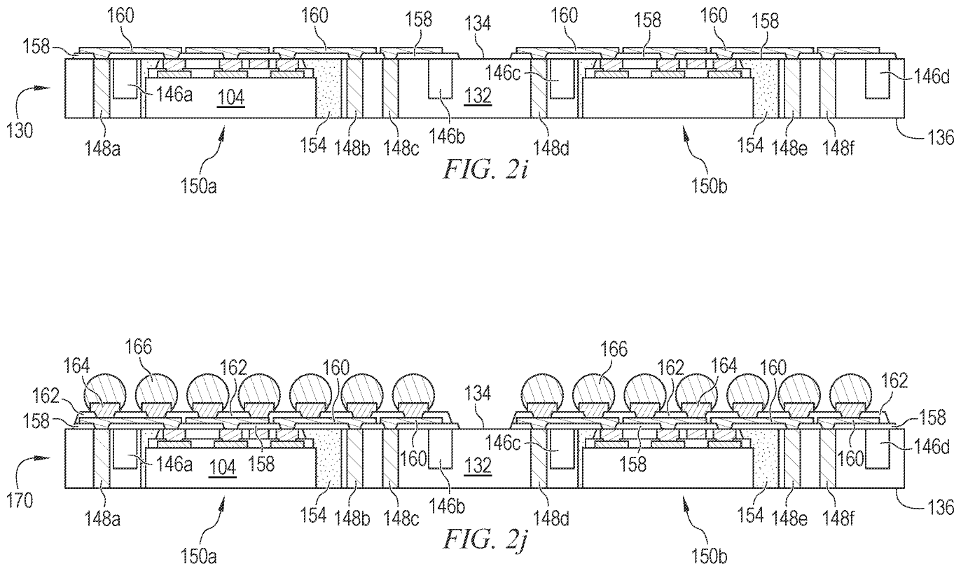

FIGS. 2a-2j illustrate a process of forming a semiconductor assembly with interposer substrate, electrical components, and interconnect structure. FIG. 2a shows a cross-sectional view of interconnect or interposer substrate 130 including core material 132, such as silicon, germanium, aluminum phosphide, aluminum arsenide, gallium arsenide, gallium nitride, indium phosphide, silicon carbide, or other bulk material for structural support. Alternatively, core material 132 can be a multi-layer flexible laminate, ceramic, copper clad laminate (CCL), glass, or epoxy molding compound. Core material 132 may contain one or more layers of SiO2, Si3N4, SiON, Ta2O5, Al2O3, solder resist, polyimide, BCB, PBO, and other material having similar insulating and structural properties. Interposer substrate 130 has a major surface 134 and major surface 136 opposite surface 134.

In FIG. 2b, vias 140a-140f are formed through interposer substrate 130 using an etching process or by LDA with laser 141. In addition, openings 142a and 142b are formed through interposer substrate 130 using an etching process or by LDA similar to laser 141. Openings 142a-142b are of sufficient size and area to contain one or more electrical components, as described infra.

In addition, discrete electrical components 146a-146d are embedded within interposer substrate 130. Discrete electrical components 146a-146d can be capacitors, inductors, resistors, diodes, transistors, and the like. In one embodiment, an opening is formed in interposer substrate 130 from surface 134 to insert the discrete electrical component. Alternatively, electrical components 146a-146d are pressed into core material 132, if the core material is a polymer, epoxy, acryl-based B-stage material, or other similar material with penetrable properties.

In FIG. 2c, vias 140a-140f are filled with electrically conductive material, such as Al, Cu, Sn, Ni, Au, Ag, or other suitable electrically conductive material, to form conductive vias 148a-148f. FIG. 2d is a top view of interposer substrate 130 with openings 142a-142b, embedded discrete electrical components 146a-146d, and conductive vias 148a-148f.

In FIG. 2e, a plurality of electrical components 150a and 150b is disposed within openings 142a and 142b, respectively. Electrical components 150a-150b are each positioned over interposer substrate 130 using a pick and place operation. For example, electrical component 150a and 150b can be similar to semiconductor die 104 from FIG. 1d with back surface 108 oriented toward surface 134 and openings 142a-142b of interposer substrate 130. Alternatively, electrical components 150a-150b can include other semiconductor die, semiconductor packages, surface mount devices, discrete electrical devices, or IPDs. FIG. 2f shows electrical components 150a-150b disposed within openings 142a-142b, respectively.

In FIG. 2g, an encapsulant or molding compound 154 is deposited over and around electrical components 150a-150b and interposer substrate 130 using a paste printing, compressive molding, transfer molding, liquid encapsulant molding, vacuum lamination, spin coating, or other suitable applicator. Encapsulant 154 can be polymer composite material, such as epoxy resin with filler, epoxy acrylate with filler, or polymer with proper filler. Encapsulant 154 is non-conductive, provides structural support, and environmentally protects the semiconductor device from external elements and contaminants.

In FIG. 2h, interposer substrate 130 and electrical components 150a-150b can be planarized with grinder 156 to expose conductive layer 124 and conductive vias 148a-148f following the encapsulation process.

In FIG. 2i, insulating layer 158 is formed over interposer substrate 130, electrical components 150a-150b, and encapsulant 154. Insulating layer 158 contains one or more layers of SiO2, Si3N4, SiON, Ta2O5, Al2O3, solder resist, polyimide, BCB, PBO, and other material having similar insulating and structural properties. Insulating layer 158 can be formed using PVD, CVD, printing, lamination, spin coating, spray coating, sintering or thermal oxidation. A portion of insulating layer 158 is removed by etching or LDA to expose conductive layer 124 and conductive vias 148a-148f.

An electrically conductive layer 160 is formed over insulating layer 158 and conductive layer 124 and conductive vias 148a-148f using PVD, CVD, electrolytic plating, electroless plating process, or other suitable metal deposition process. Conductive layer 160 can be one or more layers of Al, Cu, Sn, Ni, Au, Ag, or other suitable electrically conductive material. Portions of conductive layer 160 can be electrically common or electrically isolated depending on the design and function of electrical components attached thereto. In one embodiment, conductive layer 160 is an RDL as it redistributes the electrical signals over and across interposer substrate 130, electrical components 150a-150b, and encapsulant 154.

In FIG. 2j, insulating layer 162 is formed over insulating layer 158 and conductive layer 160. Insulating layer 162 contains one or more layers of SiO2, Si3N4, SiON, Ta2O5, Al2O3, solder resist, polyimide, BCB, PBO, and other material having similar insulating and structural properties. Insulating layer 162 can be formed using PVD, CVD, printing, lamination, spin coating, spray coating, sintering or thermal oxidation. A portion of insulating layer 162 is removed by etching or LDA to expose conductive layer 160.

An electrically conductive layer 164 is formed over insulating layer 162 and conductive layer 160 using PVD, CVD, electrolytic plating, electroless plating process, or other suitable metal deposition process. Conductive layer 164 can be one or more layers of Al, Cu, Sn, Ni, Au, Ag, or other suitable electrically conductive material. Portions of conductive layer 164 can be electrically common or electrically isolated depending on the design and function of electrical components attached thereto. In one embodiment, conductive layer 164 operates as contact pads for formation of bumps. In another embodiment, conductive layer 164 is an RDL as it redistributes the electrical signals over and across interposer substrate 130, electrical components 150a-150b, encapsulant 154, insulating layers 158 and 162, and conductive layers 160 and 164.

An electrically conductive bump material is deposited over conductive layer 164 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 164 using a suitable attachment or bonding process. In one embodiment, the bump material is reflowed by heating the material above its melting point to form balls or bumps 166. In one embodiment, bump 166 is formed over an under bump metallization (UBM) having a wetting layer, barrier layer, and adhesive layer. Bump 166 can also be compression bonded or thermocompression bonded to conductive layer 164. Bump 166 represents one type of interconnect structure that can be formed over conductive layer 164. The interconnect structure can also use bond wires, conductive paste, stud bump, micro bump, or other electrical interconnect.

The combination of interposer substrate 130, electrical components 150a-150b, encapsulant 154, insulating layers 158 and 162, and conductive layers 160 and 164 constitutes a fan-out semiconductor assembly 170 with respect to the electrical components. The separately constructed interposer substrate 130 at wafer level or panel level with conductive layers 124, 160, and 164 and conductive vias 148a-148f provides fan-out of electrical connectivity from embedded electrical components 150a and 150b. Semiconductor assembly 170 can be inspected and electrically tested for identification of KGU.

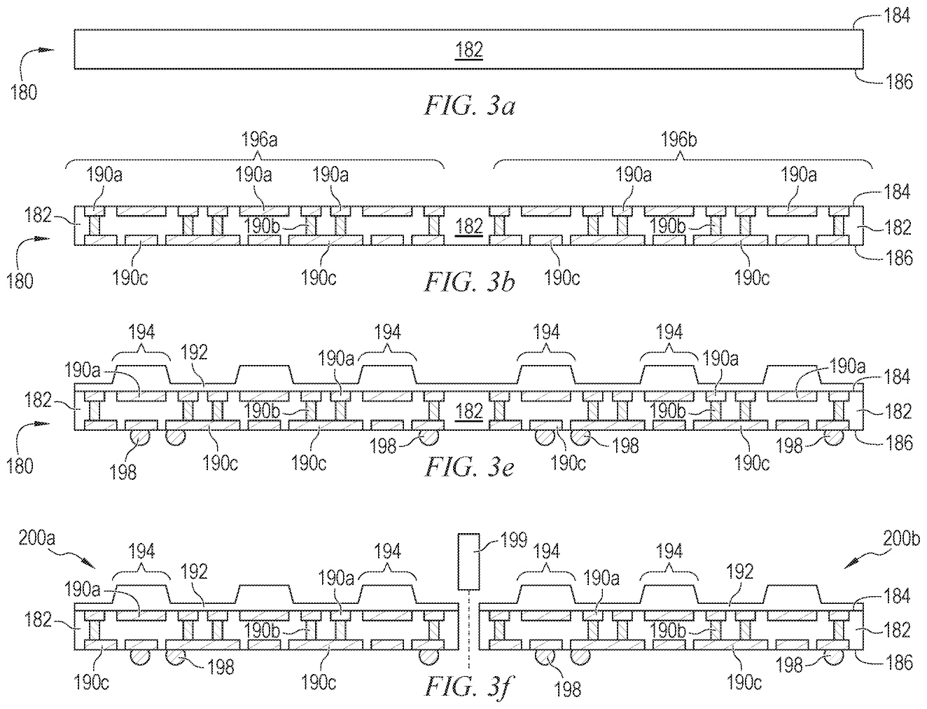

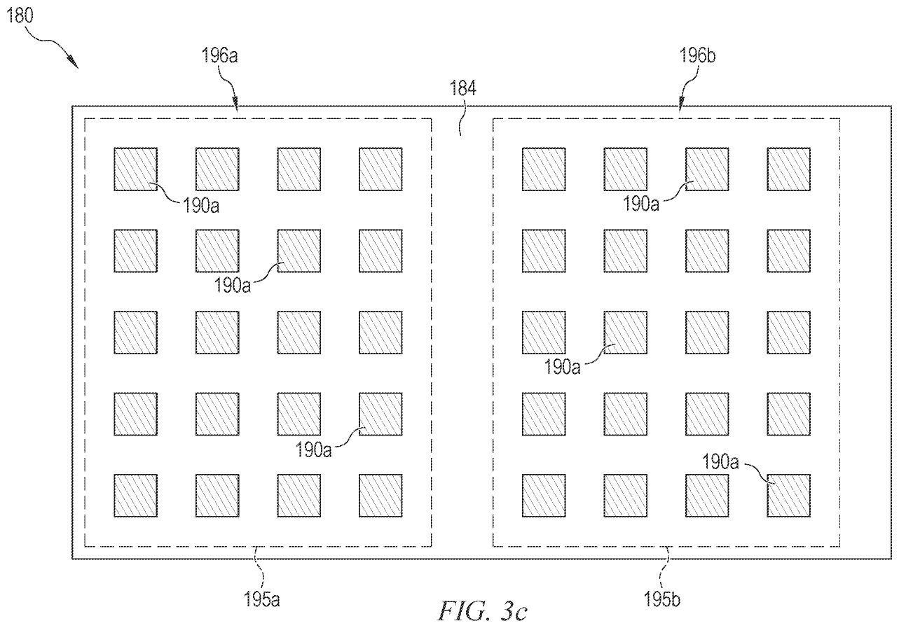

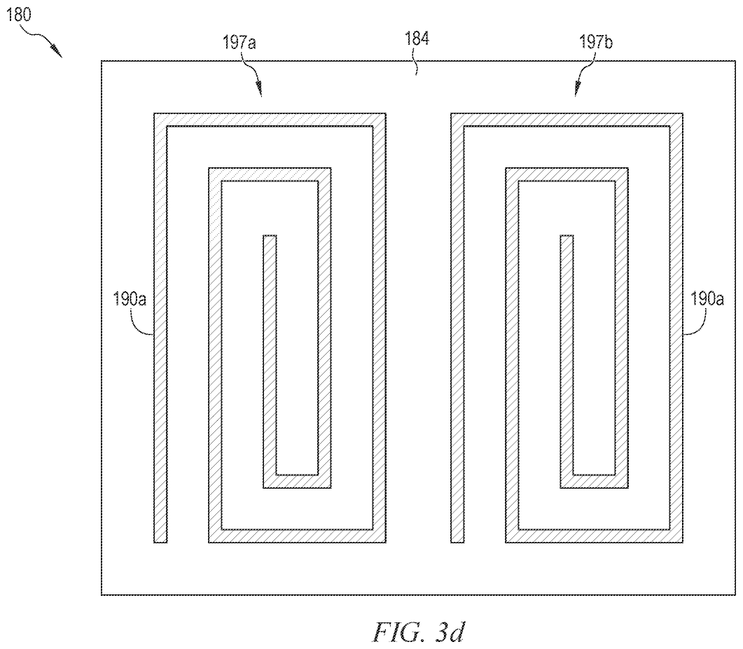

FIGS. 3a-3f illustrate a process of forming an antenna substrate. FIG. 3a shows a cross-sectional view of antenna substrate 180 including core material 182, such as silicon, germanium, aluminum phosphide, aluminum arsenide, gallium arsenide, gallium nitride, indium phosphide, silicon carbide, or other bulk material for structural support. Alternatively, core material 182 can be a multi-layer flexible laminate, ceramic, CCL, glass, or epoxy molding compound. Core material 182 may contain one or more layers of SiO2, Si3N4, SiON, Ta2O5, Al2O3, solder resist, polyimide, BCB, PBO, and other material having similar insulating and structural properties. Antenna substrate 180 has a major surface 184 and major surface 186 opposite surface 184.

In FIG. 3b, an electrically conductive layer 190 is formed over and through antenna substrate using PVD, CVD, electrolytic plating, electroless plating process, or other suitable metal deposition process. Conductive layer 190 can be one or more layers of Al, Cu, Sn, Ni, Au, Ag, or other suitable electrically conductive material. In one embodiment, conductive layer 190a is formed over surface 184 and operates as antenna 196a and 196b to transmit and receive RF signals for electrical components 150a-150b. A plurality of vias is formed through antenna substrate 180 and filled with conductive material to form conductive vias 190b. Conductive layer 190c is formed over surface 186 and electrically connects to conductive layer 190a through conductive vias 190b. In one embodiment, conductive layer 190c is an RDL as it redistributes the electrical signals over and across antenna substrate 180. Portions of conductive layers 190a, 190b, and 190c can be electrically common or electrically isolated depending on the design and function of electrical components attached thereto.

FIG. 3c is a top view of one embodiment of conductive layer 190a on surface 184 of antenna substrate 180. Conductive layer 190a includes an array of islands 195a and 195b of conductive material suitable to provide transmission and reception of RF signals, i.e., an RF antenna. Conductive layer 190a operates as multiple RF antenna 196a and 196b exposed from surface 184 of antenna substrate 180. In particular, antenna islands 195a-195b of conductive layer 190a are exposed from surface 184 to improve RF transmission and reception performance and quality. In one embodiment, antenna islands 195a of conductive layer 190a serves as a first antenna 196a electrically connected through conductive vias 190b and conductive layer 190c to provide RF transmission and reception for a first electrical component 150a. Antenna islands 195b of conductive layer 190a serves as a second antenna 196b electrically connected through conductive vias 190b and conductive layer 190c to provide RF transmission and reception for a second electrical component 150b. Antenna substrate 180 can have any number of RF antenna like 196a-196b.

FIG. 3d is a top view of another embodiment of antenna substrate 180. Conductive layer 190a includes a plurality of spiral shapes of conductive material suitable to provide transmission and reception of RF signals. In particular, the spiral shapes of conductive layer 190a are exposed from surface 184 and extend substantially across the surface of antenna substrate 180 to improve RF transmission and reception performance and quality. In one embodiment, conductive layer 190a serves as a first spiral-shaped RF antenna 197a to provide RF transmission and reception for a first electrical component 150a. Conductive layer 190a also serves as a second spiral-shaped RF antenna 197b to provide RF transmission and reception for a second electrical component 150b.

In FIG. 3e, encapsulant or molding compound 192 is deposited over conductive layer 190a and surface 184 of antenna substrate 180 using a paste printing, compressive molding, transfer molding, liquid encapsulant molding, vacuum lamination, spin coating, or other suitable applicator. Encapsulant 192 can be polymer composite material, such as epoxy resin with filler, epoxy acrylate with filler, or polymer with proper filler. Encapsulant 192 is non-conductive, provides structural support, and environmentally protects the semiconductor device from external elements and contaminants. In particular, encapsulant 192 has a greater thickness over conductive layer 190a to form encapsulant bumps 194 over antenna 196. Encapsulant 192 and encapsulant bumps 194 have a high dielectric constant (Dk) of greater than 4.0 and low dielectric dissipation factor (Df) of less than 0.01.

An electrically conductive bump material is deposited over conductive layer 190c using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 190c using a suitable attachment or bonding process. In one embodiment, the bump material is reflowed by heating the material above its melting point to form balls or bumps 198. In one embodiment, bump 198 is formed over a UBM having a wetting layer, barrier layer, and adhesive layer. Bump 198 can also be compression bonded or thermocompression bonded to conductive layer 190c. Bump 198 represents one type of interconnect structure that can be formed over conductive layer 190c. The interconnect structure can also use bond wires, conductive paste, stud bump, micro bump, or other electrical interconnect.

In FIG. 3f, antenna substrate 180 is singulated using a saw blade or laser cutting tool 199 into individual antenna substrates 200a and 200b. The individual antenna substrates 200a-200b can be inspected and electrically tested for identification of KGU pre or post singulation. Note that antenna substrates 200a-200b are constructed separate and independent from semiconductor assembly 170.

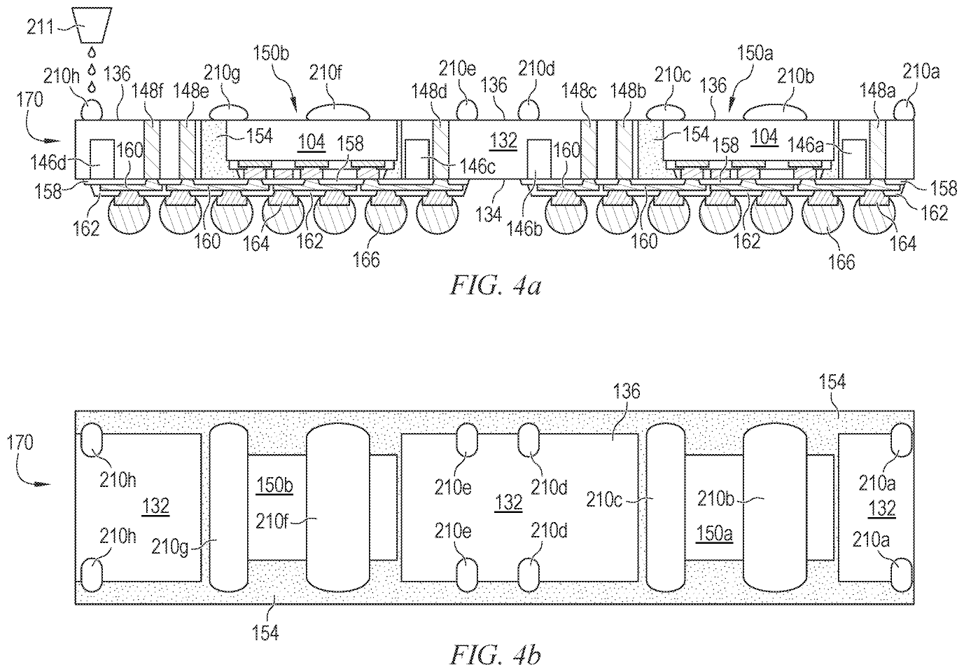

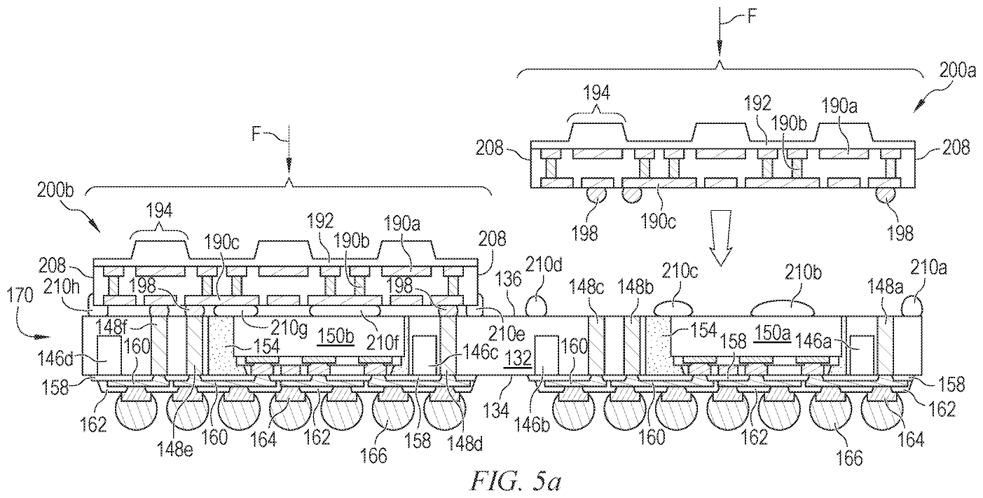

In FIG. 4a, semiconductor assembly 170 from FIG. 2j is inverted and bonding material 210 is deposited over surface 136 of the semiconductor assembly using dispenser 211, prior to attachment of antenna substrates 200a-200b. Alternatively, bonding material 210 is deposited over surface 186 of antenna substrates 200a-200b using dispenser 211, prior to attachment to semiconductor assembly 170. Bonding material 210 can be epoxy or other polymer based adhesive with optional SiO2 or Al2O3 fillers, for example, Dow Corning SE4450 and EA6900, Momentive LA650S, Henkel FP4451, Namics SUF1583-33, and/or Panasonic ADE480D. Bonding material 210 provides structural support and thermal conductivity between later-added antenna substrates 200a-200b and semiconductor assembly 170. In particular, bonding material 210a is deposited over core material 132 and encapsulant 154, bonding material 210b is deposited over encapsulant 154 and electrical component 150a, bonding material 210c is deposited over encapsulant 154 and electrical component 150a, bonding material 210d is deposited over encapsulant 154 and core material 132, bonding material 210e is deposited over encapsulant 154 and core material 132, bonding material 210f is deposited over encapsulant 154 and electrical component 150b, bonding material 210g is deposited over encapsulant 154 and electrical component 150b, and bonding material 210h is deposited over encapsulant 154 and core material 132. FIG. 4b is a top view of bonding material 210a-210h deposited over surface 136 of semiconductor assembly 170, as described above.

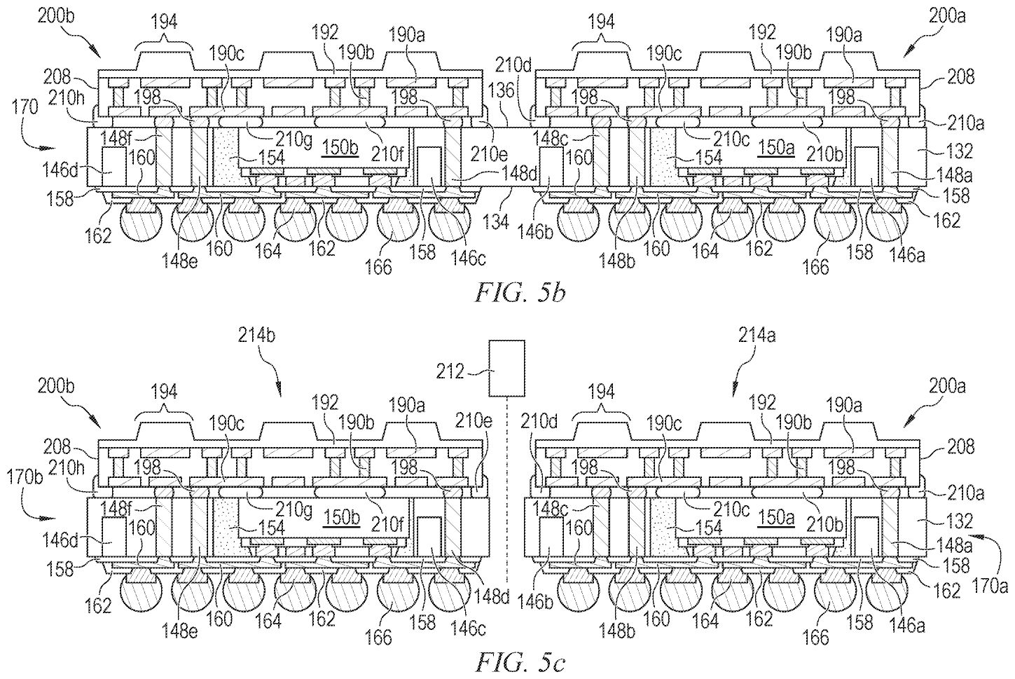

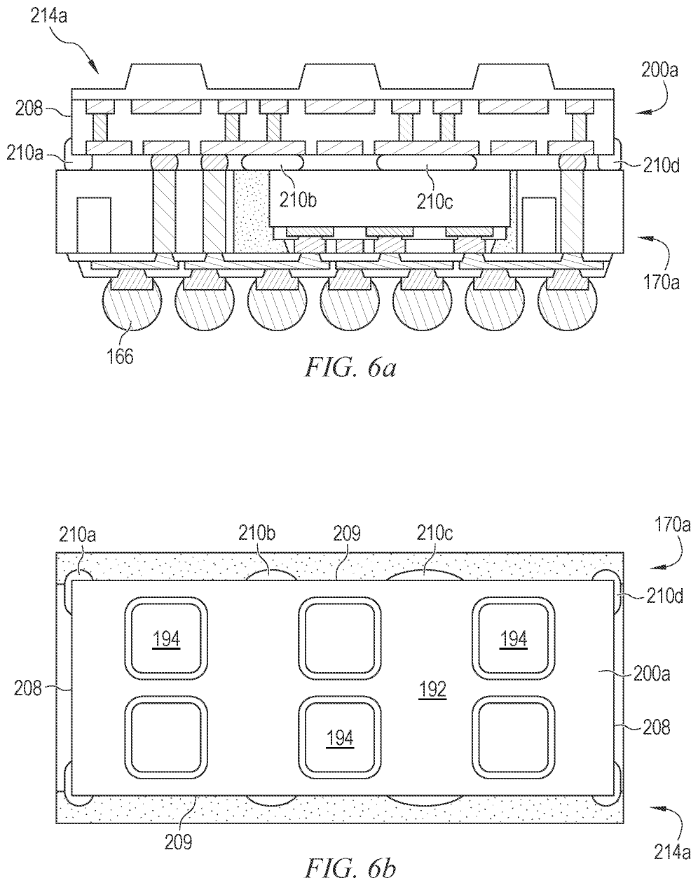

In FIG. 5a, antenna substrates 200a and 200b are disposed over semiconductor assembly 170. In particular, antenna substrate 200a is disposed over the portion of semiconductor assembly 170 having electrical component 150a disposed within opening 142a, and antenna substrate 200b is disposed over the portion of the semiconductor assembly having electrical component 150b disposed within opening 142b. Antenna substrates 200a and 200b are brought into contact with bonding material 210 as each is pressed toward surface 136 of semiconductor assembly 170 with force F. Antenna substrates 200a-200b compress bonding material 210a-210h under force F. As bonding material 210a-210h compresses, a portion of the bonding material extends outside a footprint of antenna substrate 200a and creeps or extends up sides surfaces 208 and 209 of antenna substrates 200a-200b, see FIG. 6b. Bumps 198 are reflowed or thermal compression bonding (TCB) to mechanically and electrically connect antenna substrates 200a-200b to conductive vias 148a-148f. Bonding material 210 is at least partially cured during reflow or TCB. FIG. 5b shows antenna substrates 200a and 200b bonded to surface 136 of semiconductor assembly 170 with bonding material 210a-210h and bumps 198.

In FIG. 5c, semiconductor assembly 170 is singulated using a saw blade or laser cutting tool 212 into individual AiP modules 214a and 214b. AiP module 214a contains separately formed semiconductor assembly 170a and antenna substrate 200a. AiP module 214b contains separately formed semiconductor assembly 170b and antenna substrate 200b. The individual AiP modules 214a-214b can be inspected and electrically tested for identification of KGU post singulation.

FIG. 6a shows AiP module 214a post singulation. Bumps 166 can be formed post singulation. Electrical component 150a is electrically connected through conductive layers 112, 124, 160, and 164 and bumps 166 to external components and systems. Electrical component 150a is further electrically connected through conductive layers 112, 124, and 160, conductive vias 148a-148c, bumps 198, conductive layer 190c, and conductive vias 190b to conductive layer 190a, again operating as antenna area 196. The separately constructed interposer substrate 130 at wafer level or panel level with conductive layers 112, 124, 160, and 164 and conductive vias 148a-148c provides fan-out of electrical connectivity from embedded electrical component 150a to conductive layers 190a-190c in antenna substrate 200a, as well as antenna area 196. Bonding material 210a-210d assists with the joining of semiconductor assembly 170a and antenna substrate 200a. Discrete electrical components 146a-146b provide additional electrical functionality. FIG. 6b is a top view of AiP module 214a with bonding material 210a-210b extending outside a footprint of antenna substrate 200a and extending up side surfaces 208 and 209. Encapsulant 192 with encapsulant bumps 194 covers antenna substrate 200a. AiP module 214a provides a long cycle time with sequential wafer level AiP processes. Antenna substrate 200a is constructed separately from semiconductor assembly 170a. Antenna substrate 200a is similar in area as semiconductor assembly 170a, allowing space for bonding material 210a-210d. The KGD/KGU status of semiconductor assembly 170a and antenna substrate 200a at multiple manufacturing milestones increases AiP module 214a process yield. AiP module 214b follows a similar structure and function.

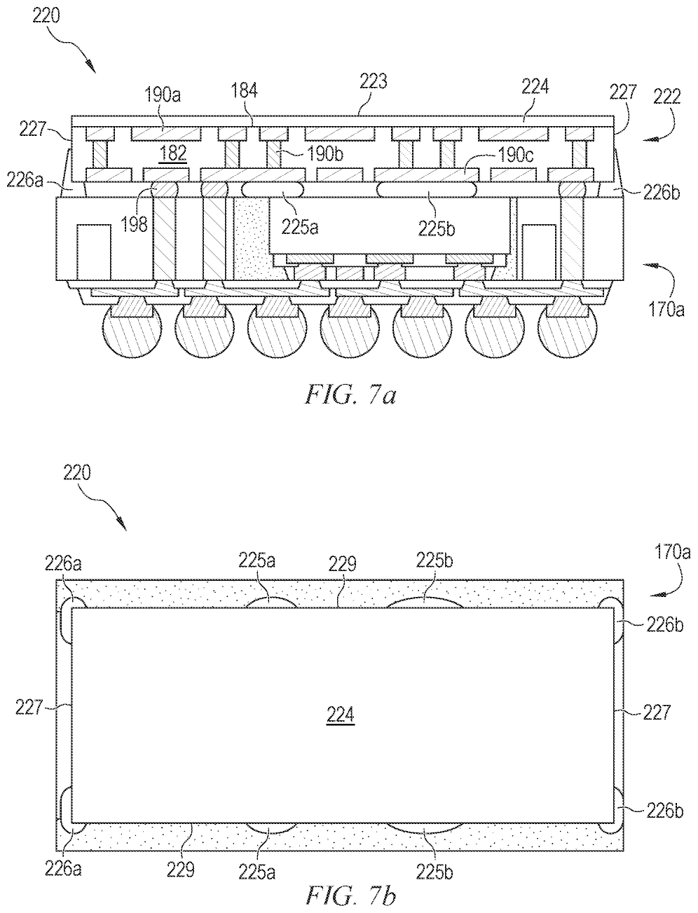

In another embodiment, FIG. 7a shows AiP module 220 with antenna substrate 222 made similar to antenna substrate 200a. Encapsulant 224 is deposited over surface 184 and conductive layer 190a of antenna substrate 222. Components having a similar function are assigned the same reference number. In this case, surface 223 of encapsulant 224 is planar, i.e., without encapsulant bumps like 194. Bonding material 225 is deposited over semiconductor assembly 170a from FIG. 6a, prior to attachment of antenna substrate 222, similar to FIGS. 5a-5c. Antenna substrate 222 compresses bonding material 225a-225b under force F. Bonding material 225 provides structural support and thermal conductivity between antenna substrate 222 and semiconductor assembly 170a. After attachment of antenna substrate 222 to semiconductor assembly 170a, edge bonding material 226a is deposited over core material 132 and encapsulant 154, and further creeps or extends up side surface 227 and 229 of antenna substrate 222, and edge bonding material 226b is deposited over encapsulant 154 and core material 132, and further creeps or extends up side surfaces 227 and 229 of the antenna substrate. FIG. 7b is a top view of bonding material 225a-225b deposited between semiconductor assembly 170a and antenna substrate 222 pre-attachment, and edge bonding material 226a-226b deposited between semiconductor assembly 170a and antenna substrate 222 and over side surfaces 227 and 229 of the antenna substrate post attachment.

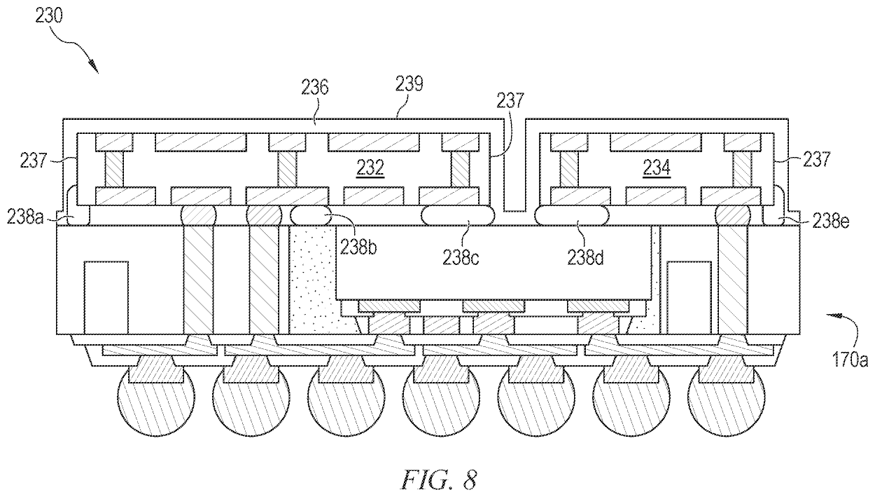

In another embodiment, FIG. 8 shows AiP module 230 with separate antenna substrates 232 and 234, each made similar to antenna substrates 200a-200b. Electrical component 150a has separate electrical connection to antenna substrate 232 and antenna substrate 234. Accordingly, electrical component 150a has available two or more antennas for transmission and reception of RF signals. Bonding material 238 is deposited over semiconductor assembly 170a from FIG. 6a, prior to attachment of antenna substrates 232 and 234, similar to FIGS. 5a-5c. Antenna substrates 232 and 234 compress bonding material 238a-238e under force F. As bonding material 238a-238e compresses, a portion of the bonding material extends outside a footprint of antenna substrate 200a and creeps or extends up sides surfaces 237 of antenna substrates 232 and 234. Bonding material 238 provides structural support and thermal conductivity between antenna substrates 232-234 and semiconductor assembly 170a. In particular, bonding material 238a is deposited over core material 132 and encapsulant 154, bonding material 238b is deposited over core material 132 and encapsulant 154, bonding material 238c is deposited over encapsulant 154 and electrical component 150a, bonding material 238d is deposited over encapsulant 154 and electrical component 150a, and bonding material 238e is deposited over encapsulant 154 and core material 132. Encapsulant 236 is conformally deposited over surface 184 and conductive layer 190a of antenna substrate 180 and further over side surfaces 237 between antenna substates 232 and 234, extending to bonding material 238 and back surface 108 of electrical component 150a. In this case, surface 239 of encapsulant 236 is planar, i.e., without encapsulant bumps like 194. In one embodiment, encapsulant 236 is a vacuum laminated low Df film less than 0.01 to form an air cavity around antenna substrates 232 and 234.

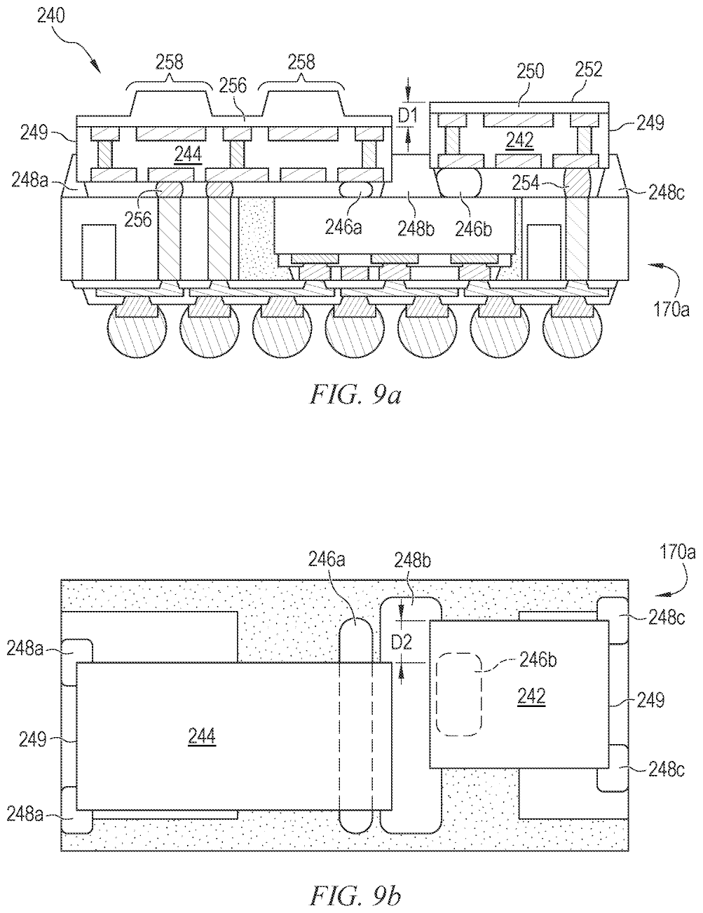

In another embodiment, FIG. 9a shows AiP module 240 with separate antenna substrates 242 and 244, each made similar to antenna substrates 200a-200b. Electrical component 150a has separate electrical connection to antenna substrate 242 and antenna substrate 244. Accordingly, electrical component 150a has available two or more antennas for transmission and reception of RF signals. Bonding material 246 is deposited over semiconductor assembly 170a from FIG. 6a, prior to attachment of antenna substrates 242 and 244, similar to FIGS. 5a-5c. Bonding material 248 is also deposited over semiconductor assembly 170a, similar to FIGS. 5a-5c. Antenna substrates 242 and 244 compress bonding material 246a-246b and bonding material 248a-248c under force F. As bonding material 248a-248c compresses, a portion of the bonding material extends outside a footprint of antenna substrate 242 and creeps or extends up sides surfaces 249 of antenna substrates 242 and 244. Bonding material 246 and 248 provides structural support and thermal conductivity between antenna substrates 242-244 and semiconductor assembly 170a. Note that antenna substrate 242 is vertically offset with respect to antenna substrate 244 by distance D1 of greater than 5.0 μm. That is, antenna substrate 242 has a higher stand-off and antenna substrate 244 has a lower stand-off, as compared to antenna substrate 242. Accordingly, bonding material 246b is thicker than bonding material 246a. Alternatively, antenna substrate 242 has a lower stand-off and antenna substrate 244 has a higher stand-off, as compared to antenna substrate 242. In that case, bonding material 246b is thinner than bonding material 246a. Bonding material 248a-248c can be deposited either prior to attachment of antenna substrates 242 and 244, or post attachment of the antenna substrates. Encapsulant 250 is deposited over surface 184 and conductive layer 190a of antenna substrate 242. In this case, surface 252 of encapsulant 250 is planar, i.e., without encapsulant bumps like 194. Encapsulant 256 is deposited over surface 184 and conductive layer 190a of antenna substrate 244. In this case, encapsulant 256 includes encapsulant bumps 258.

FIG. 9b is a top view of bonding material 246a-246b deposited between semiconductor assembly 170a and antenna substrates 242 and 244, and bonding material 248a-248c deposited between semiconductor assembly 170a and antenna substrates 242 and 244 and over side surfaces 249 of the antenna substrates. Encapsulant 250 covers antenna substrate 242 and encapsulant 256 covers antenna substrate 244, as attached to semiconductor assembly 170a. Note that antenna substrate 242 is horizontally offset with respect to antenna substrate 244 by distance D2 of greater than 5.0 μm.

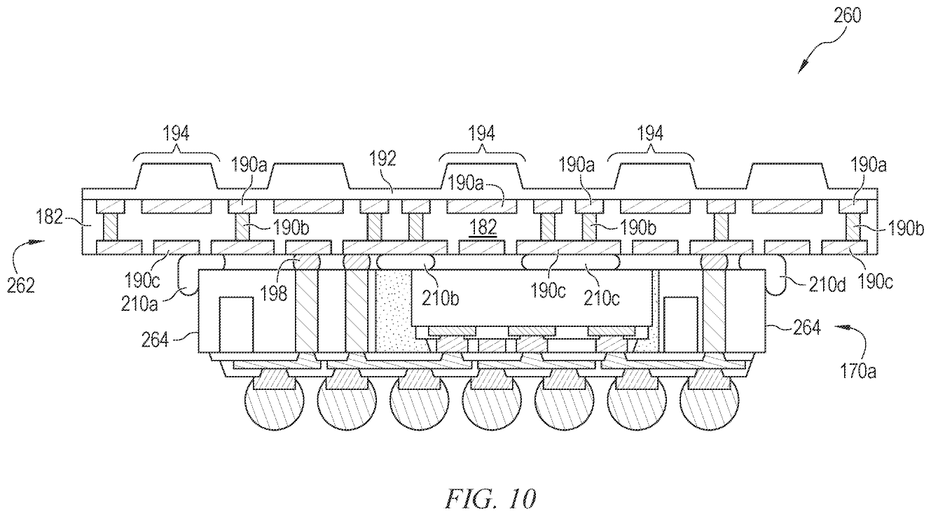

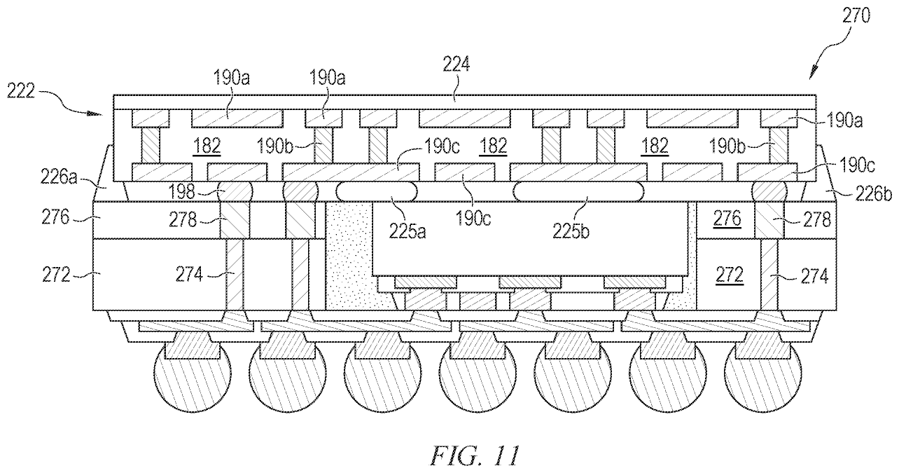

In another embodiment, FIG. 10 shows AiP module 260 with antenna substrate 262, made similar to antenna substrates 200a-200b, fan-out to extend beyond a footprint of semiconductor assembly 170a. Bonding material 210a-210d is deposited over semiconductor assembly 170a from FIG. 6a, prior to attachment of antenna substrates 262, similar to FIGS. 5a-5c. Antenna substrate 262 compresses bonding material 210a-210b under force F. Bonding material 210 provides structural support and thermal conductivity between antenna substrate 262 and semiconductor assembly 170a. Bonding material 210a and 210d extend over side surface 264 of semiconductor assembly 170a. Encapsulant 192 with encapsulant bumps 194 is deposited over surface 184 and conductive layer 190a of antenna substrate 200a.

In another embodiment, FIG. 11 shows AiP module 270, similar to AiP 220 in FIGS. 7a-7b, with the core material of the interposer substrate constructed in multiple layers. Core material 272 can be made similar to core material 130 in FIG. 2a. Conductive vias 274 extend through core material 272, similar to conductive vias 148a-148f in FIG. 2c. Core material 276 is formed over or bonded to core material 272. Core material 276 can be made similar to core material 130 in FIG. 2a. Conductive vias 278 extend through core material 272, similar to conductive vias 148a-148f in FIG. 2c. The coefficient of thermal expansion (CTE) of core material 272 is made less than the CTE of core material 276 to reduce warpage of AiP module 270. In one embodiment, the CTE of core material 272 is 5.0-8.0 ppm/° C., and the CTE of core material 276 is 10.0-15.0 ppm/° C.

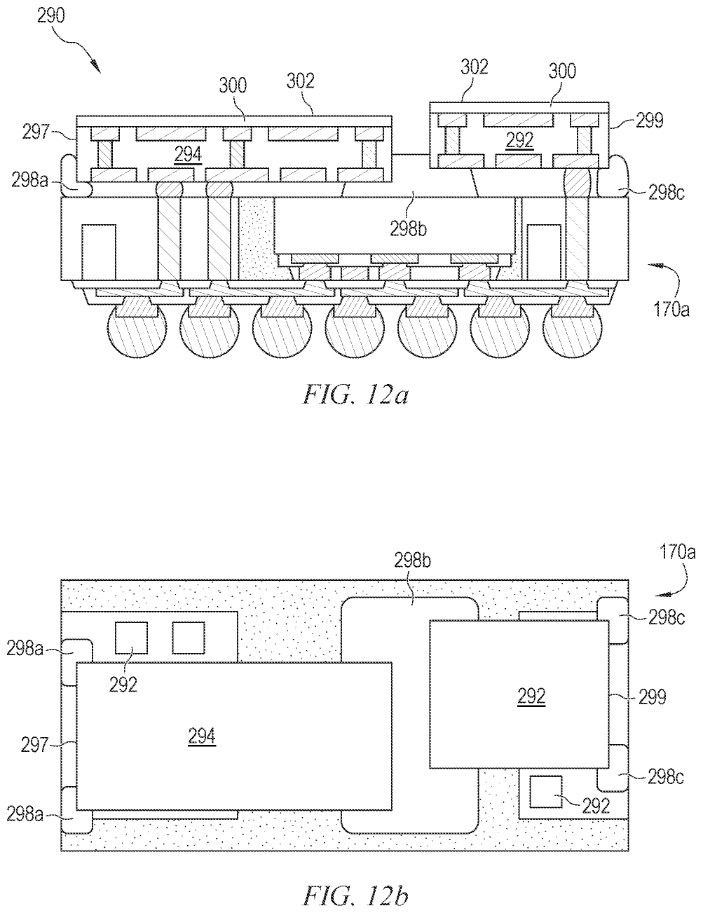

In another embodiment, FIG. 12a shows AiP module 290, similar to AiP 240 in FIG. 9a, with separate antenna substrates 292 and 294, each made similar to antenna substrates 200a-200b. Bonding material 298 is deposited over semiconductor assembly 170a from FIG. 6a, prior to attachment of antenna substrates 292 and 294, similar to FIGS. 5a-5c. Antenna substrates 292 and 294 compress bonding material 298a-298c under force F. As bonding material 298a-298c compresses, a portion of the bonding material extends outside a footprint of antenna substrates 292 and 294 and creeps or extends up sides surfaces 299 of antenna substrate 292 and side surface 297 of antenna substrate 294. Bonding material 298 provides structural support and thermal conductivity between antenna substrates 292-294 and semiconductor assembly 170a. Note that antenna substrate 292 is offset with respect to antenna substrate 294, similar to FIG. 9a. Encapsulant 300 deposited over surface 184 and conductive layer 190a of antenna substrates 292 and 294. In this case, surface 302 of encapsulant 300 is planar, i.e., without encapsulant bumps like 194. FIG. 12b shows surface mount devices 292 disposed over core material 130.

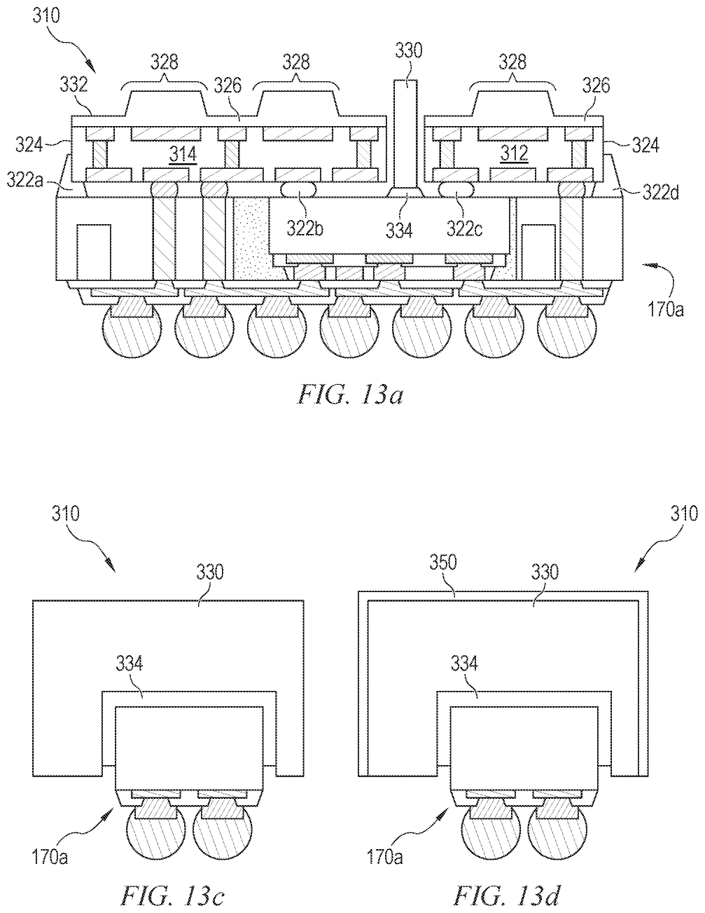

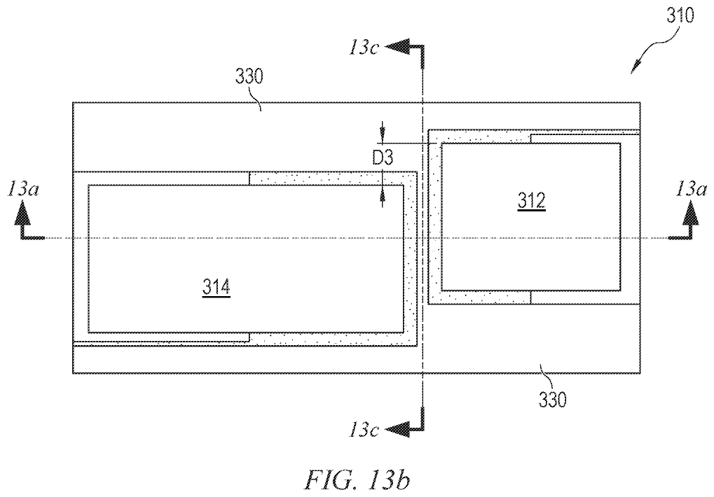

In another embodiment, FIG. 13a shows AiP module 310, with separate antenna substrates 312 and 314, each made similar to antenna substrates 200a-200b. Bonding material 322 is deposited over semiconductor assembly 170a from FIG. 6a, prior to attachment of antenna substrates 312 and 314, similar to FIGS. 5a-5c. Antenna substrates 312 and 314 compress bonding material 322a-322d under force F. As bonding material 322a-322c compresses, a portion of the bonding material extends outside a footprint of antenna substrates 312 and 314 and creeps or extends up sides surfaces 324 of antenna substrate 312 and side surface 326 of antenna substrate 314. Encapsulant 326 is deposited over surface 184 and conductive layer 190a of antenna substrates 312 and 314 with encapsulant bumps 328.

A thermally conductive layer 330 is formed over surface 332 of encapsulant 326 and between antenna substrates 312 and 314, as shown in FIG. 13b. Note that antenna substrate 312 is horizontally offset with respect to antenna substrate 314 by distance D3 of greater than 10.0 μm. Conductive layer 330 extends to back surface 108 of electrical component 150a. A thermal interface material (TIM) 334 assists with heat dissipation from electrical component 150a to thermally conductive layer 330. Accordingly, thermally conductive layer 330 operates as a heat sink. Conductive layer 330 can be one or more layers of Al, Cu, Sn, Ni, Au, Ag, or other suitable thermally conductive material. FIG. 13c is a cross-sectional view of AiP module 310 in a direction normal to FIG. 13a. Heat sink 330 can be flat bottom, overhang, or wings to properly dissipate heat from electrical component 150a.

Electrical components 150a-150b may contain IPDs that are susceptible to or generate EMI, RFI, harmonic distortion, and inter-device interference. For example, the IPDs contained within electrical components 150a-150b provide the electrical characteristics needed for high-frequency applications, such as resonators, high-pass filters, low-pass filters, band-pass filters, symmetric Hi-Q resonant transformers, and tuning capacitors. In another embodiment, electrical components 150a-150b contain digital circuits switching at a high frequency, which could interfere with the operation of IPDs in the assembly.

To address EMI, RFI, harmonic distortion, and inter-device interference, electromagnetic shielding material 350 is applied over antenna substrate 310, as shown in FIG. 13d. Electromagnetic shielding material 350 can be one or more layers of Al, Cu, Sn, Ni, Au, Ag, or other suitable conductive material. Alternatively, electromagnetic shielding material 350 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference. Shielding material 350 can be formed in lieu of thermally conductive material 330. Shielding material 350 can be formed under thermally conductive material 330.

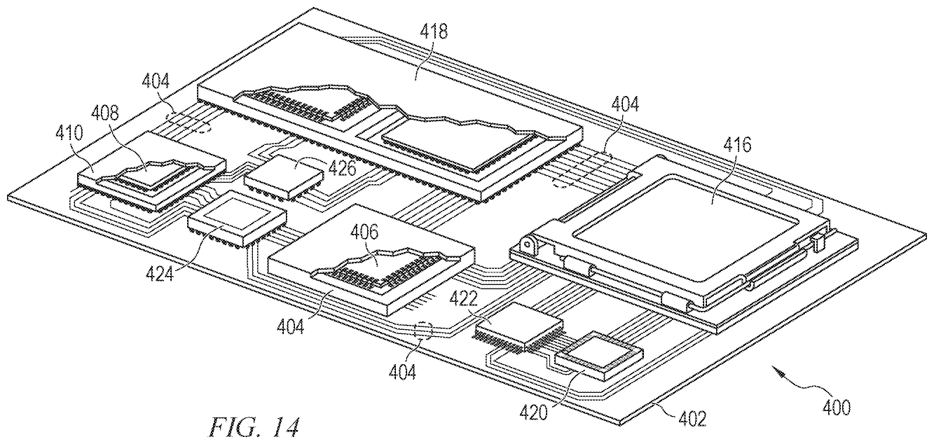

FIG. 14 illustrates electrical device 400 having a chip carrier substrate or PCB 402 with a plurality of semiconductor packages disposed on a surface of PCB 4O2, including AiP modules 214, 220, 230, 240, 260, 270, 290, and 310. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 14, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a semiconductor assembly;
an antenna substrate formed separate from the semiconductor assembly and mounted to the semiconductor assembly; and
a bonding material disposed between the antenna substrate and semiconductor assembly.

2. The semiconductor device of claim 1, further including an encapsulant deposited over the antenna substate.

3. The semiconductor device of claim 1, wherein the bonding material extends over a side surface of the antenna substrate.

4. The semiconductor device of claim 1, wherein the antenna substrate includes a first antenna substrate and a second antenna substrate disposed over the semiconductor assembly.

5. The semiconductor device of claim 4, wherein the first antenna substrate is offset with respect to the second antenna substrate.

6. The semiconductor device of claim 1, wherein the antenna substrate fans out from the semiconductor assembly.

7. A semiconductor device, comprising:
a semiconductor assembly; and
an antenna substrate formed separate from the semiconductor assembly and mounted to the semiconductor assembly with a bonding material.

8. The semiconductor device of claim 7, further including an encapsulant deposited over the antenna substate.

9. The semiconductor device of claim 7, wherein the bonding material extends over a side surface of the antenna substrate.

10. The semiconductor device of claim 7, wherein the antenna substrate includes a first antenna substrate and a second antenna substrate disposed over the semiconductor assembly.

11. The semiconductor device of claim 10, wherein the first antenna substrate is offset with respect to the second antenna substrate.

12. The semiconductor device of claim 7, wherein the antenna substrate fans out from the semiconductor assembly.

13. The semiconductor device of claim 7, wherein the semiconductor assembly includes multiple layers of core material with different coefficient of thermal expansions.

14. A method of making a semiconductor device, comprising:
providing a semiconductor assembly;
forming an antenna substrate separate from the semiconductor assembly;
mounting the antenna substrate to the semiconductor assembly; and
disposing a bonding material between the antenna substrate and semiconductor assembly.

15. The method of claim 14, further including depositing an encapsulant over the antenna substate.

16. The method of claim 14, wherein the bonding material extends over a side surface of the antenna substrate.

17. The method of claim 14, wherein forming the antenna substrate includes:
forming a first antenna substrate;
forming a second antenna substrate; and
disposing the first antenna substrate and second antenna substrate over the semiconductor assembly.

18. The method of claim 17, wherein the first antenna substrate is offset with respect to the second antenna substrate.

19. The method of claim 14, wherein the antenna substrate fans out from the semiconductor assembly.

20. A method of making a semiconductor device, comprising:
providing a semiconductor assembly; and
forming an antenna substrate separate from the semiconductor assembly and mounted to the semiconductor assembly with a bonding material.

21. The method of claim 20, further including depositing an encapsulant over the antenna substate.

22. The method of claim 20, wherein the bonding material extends over a side surface of the antenna substrate.

23. The method of claim 20, wherein forming the antenna substrate includes:
forming a first antenna substrate;
forming a second antenna substrate; and
disposing the first antenna substrate and second antenna substrate over the semiconductor assembly.

24. The method of claim 23, wherein the first antenna substrate is offset with respect to the second antenna substrate.

25. The method of claim 20, wherein the antenna substrate fans out from the semiconductor assembly.
